(19) United States
(12) Patent Application Publication
(10) Pub. No.: US 2026/0101471 A1
(43) Pub. Date: Apr. 9, 2026

(54) FLEXIBLE COLD PLATE ASSEMBLY

(71) Applicant: Nvidia Corporation, Santa Clara, CA (US)

(72) Inventors: Gabriele Gorla, Santa Clara, CA (US); John Franz, Tomball, TX (US); David Brien Haley, Beaverton, OR (US); Amit Kulkarni, San Jose, CA (US); Andrew Bell, San Francisco, CA (US); Elad Mentovich, Tel Aviv (IL); Ryan Wells, Raleigh, NC (US); Tahir Cader, Spokane Valley, WA (US); Giovanni Federico, Sheffield (GB); Eyal Setter, Aloney Abba (IL)

(21) Appl. No.: 19/193,730

(22) Filed: Apr. 29, 2025

Related U.S. Application Data
(60) Provisional application No. 63/703,629, filed on Oct. 4, 2024.

(51) Int. Cl. H05K 7/20

(52) U.S. Cl. CPC H05K 7/20254; H05K 7/20772

(57) ABSTRACT

A flexible cold plate assembly may include a flexible cold plate which allows for conformance or flexing to support warping associated with an underlying computing component. The conformance or flexing may be based, at least in part, on one or more of a thin base plate, on heat removal surface extensions of the flexible cold plate assembly having multiple cross-cuts therein, or a distribution seal having conformance or flexing properties. The cross-cuts may be perpendicular to a direction of flow of a fluid through the heat removal surface extensions to provide the conformance or flexing in the flexible cold plate.

### CROSS-REFERENCE TO RELATED APPLICATION(S)

This is a non-provisional application that is related to and that claims the benefit of priority from U.S. provisional patent application Ser. No. 63/703,629, filed Oct. 4, 2024, and entitled “FLEXIBLE COLD PLATE ASSEMBLY,” the entire contents of which is incorporated by reference herein and form a part of this specification for all intents and purposes.

### TECHNICAL FIELD

This disclosure generally relates to liquid cooling and specifically relates to flexible cold plates assemblies in computer environments, such as datacenters.

### BACKGROUND

Computer environments such as datacenters may be subject to liquid cooling. Liquid cooling may use cold plates to interface with computing components of a computer module.

### BRIEF DESCRIPTION OF DRAWINGS

FIG. 1A is an illustration of a flexible cold plate having heat removal surface extensions, discontinuities within the heat removal surface extensions, and a thin base plate, in at least one embodiment;

FIG. 1B is an illustration of a datacenter subject to the flexible cold plate assembly of FIG. 1A, in at least one embodiment;

FIG. 2A is an illustration of computer module aspects of a flexible cold plate assembly, in at least one embodiment;

FIG. 2B is an illustration of cross-section aspects of a flexible cold plate assembly, in at least one embodiment;

FIG. 2C is an illustration of further aspects of a flexible cold plate assembly, in at least one embodiment;

FIG. 2D is an illustration of cross-sectional and plan view aspects of heat removal surface extensions and discontinuities that are perpendicular to a direction of flow of a fluid through the heat removal surface extensions in a flexible cold plate assembly, in at least one embodiment;

FIG. 2E is an illustration of cross-sectional view aspects of a distribution seal having a top distribution seal portion and a bottom distribution seal portion, in at least one embodiment;

FIG. 3A is an illustration of a flexible cold plate assembly with a distribution seal having flow restrictions to block or limit fluid from reaching portions of the flexible cold plate in a flexible cold plate assembly, in at least one embodiment;

FIG. 3B is a detailed illustration of a flexible cold plate assembly with a distribution seal having a spring between a top plate and a bottom plate to perform further conforming or flexing in the distribution seal of a flexible cold plate assembly, in at least one embodiment;

FIG. 3C is an illustration of features to provide conformance or flexing in boundary areas of a flexible cold plate, in at least one embodiment;

FIG. 4 illustrates rack aspects in a system subject to a flexible cold plate assembly, according to at least one embodiment;

FIG. 5A illustrates a process flow for a system having at least one flexible cold plate assembly, in at least one embodiment;

FIG. 5B illustrates yet another process flow for a system having at least one flexible cold plate assembly, in at least one embodiment;

FIG. 6A illustrates an example datacenter, in which at least one embodiment from FIGS. 1A-5B may be used;

FIG. 6B is a block diagram that schematically illustrates a computing system that may be a data center or a High-Performance Computing (HPC) cluster, in which at least one embodiment from FIGS. 1A-5B may be used;

FIG. 6C illustrates a computer system, according to at least one example, in which at least one embodiment from FIGS. 1A-5B may be used; and

FIG. 7 illustrates an example network configuration of components that can be used to implement aspects of various embodiments, such as to provide, generate, modify, encode, process, fuse, and/or transmit generated image data, calculated measurements, or other such content.

### DETAILED DESCRIPTION

Package sizes of cold plates have been increasing and may be subject to limitations in dimensions relative to a computer component. There may be silicon features of a die, a chip, or other silicon package (altogether referred to herein as a computing feature, component, or device). The increase in package sizes may cause issues, such as warping, in certain applications. Further, warping in a cold plate may result in gaps between a cold plate and an underlying computing components or features. Consequently, the gaps may cause an uneven thermal connection between the cold plate and the computing component at any interface there between. Further, there may be stresses on brittle silicon and on solder joints of a ball grid array (BGA) of a circuit board supporting such solder joints. The stresses may be from handling of the cold plate and its attachment forces and during servicing events associated with lidless or exposed die packages. In addition, a lidless cold plate may be subject to an issue of deflection under pressure from fluid flow.

A flexible cold plate assembly, as described herein may allow improved contact and heat removal from an underlying computing component that may warp due to heat and other factors during performance of a workload. The flexible cold plate assembly may include a flexible cold plate formed of one or more of a thin base plate or heat removal surface extensions having discontinuities (such as crosscuts on fins or microchannels of the cold plate allow flexing of the cold plate along with or separately from the thin base plate). There may be seals and other components within the flexible cold plate assembly to direct fluid used with the heat removal surface extensions. Further, when a thin base plate is used, the combination, along with the heat removal surface extensions, may allow, in part, the flexible cold plate to be further conforming or flexing with respect to warping in the underlying computing component.

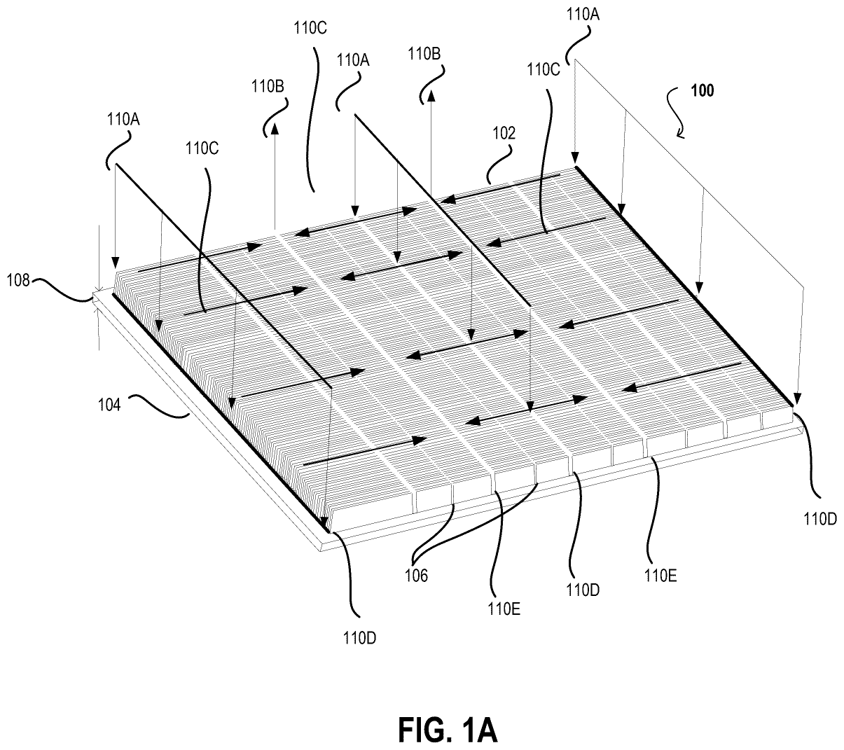

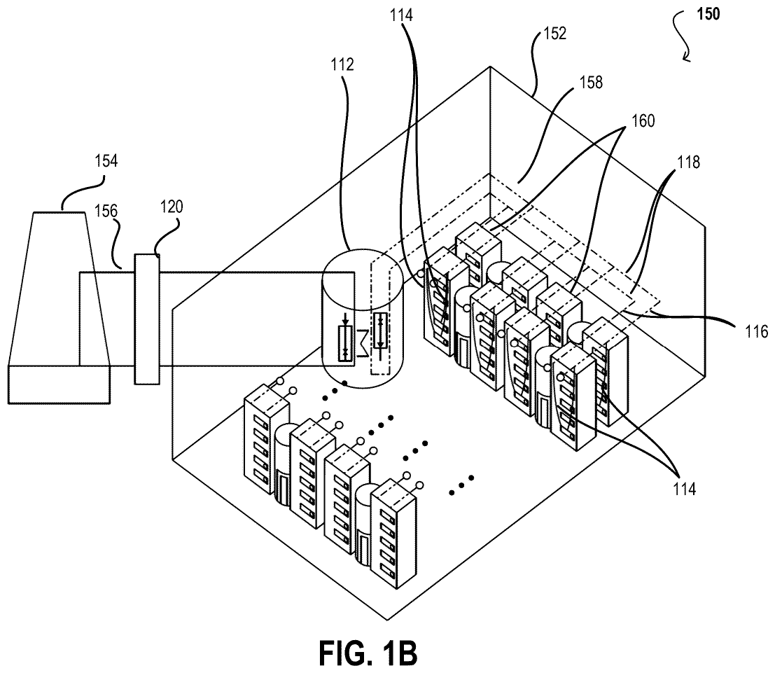

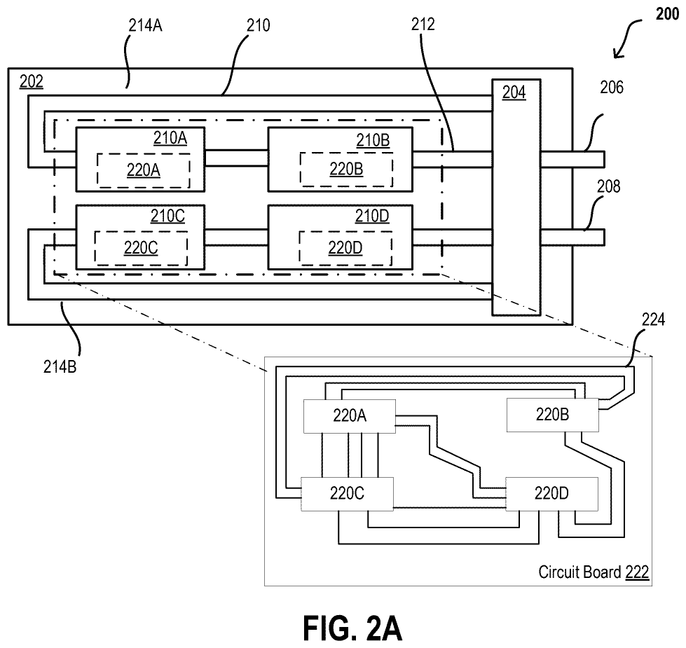

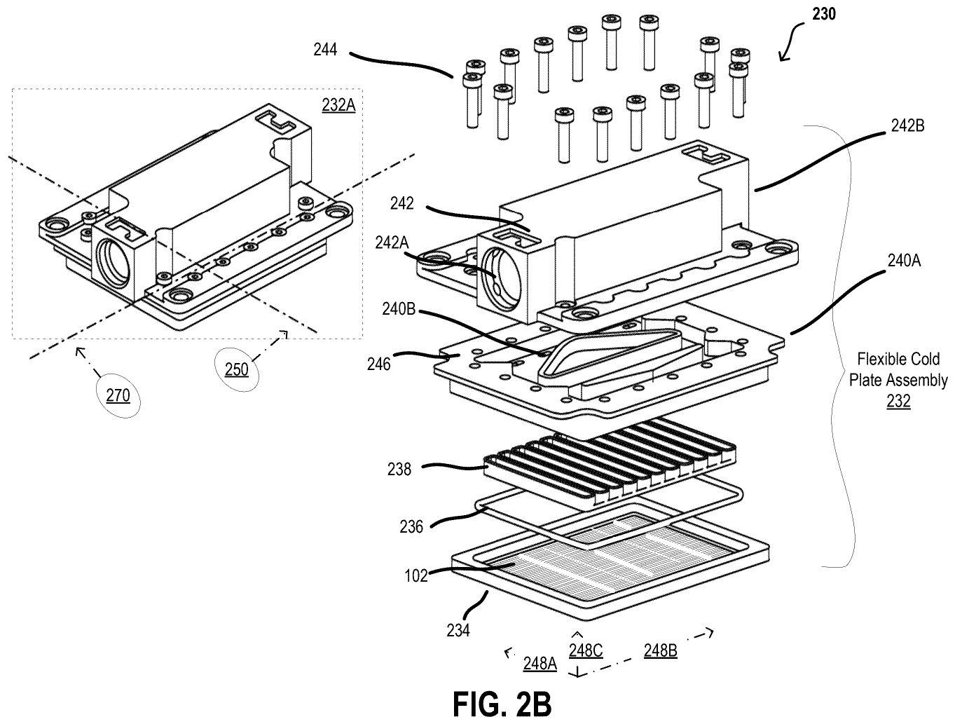

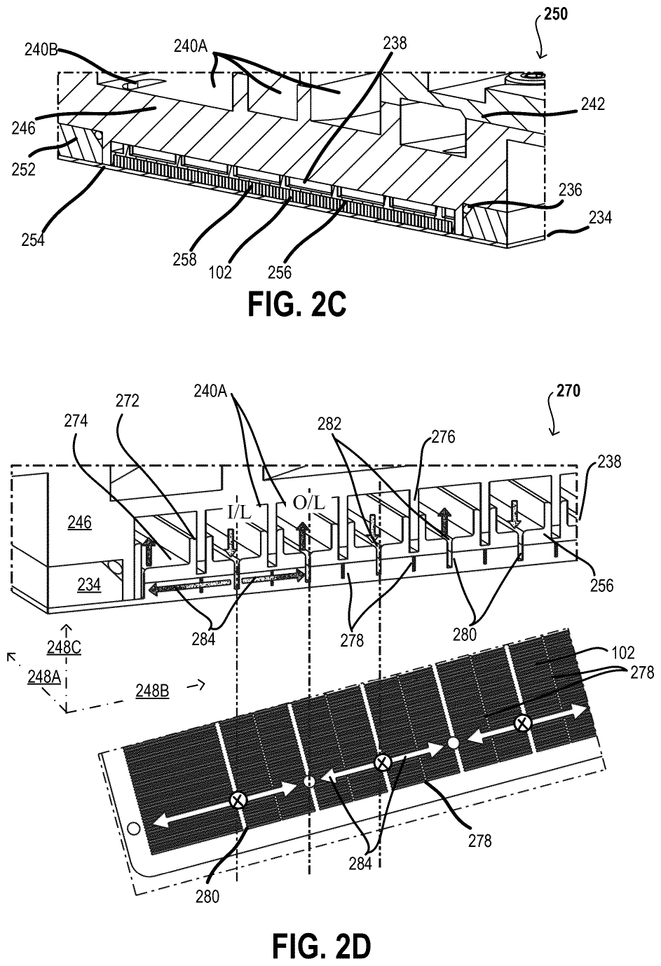

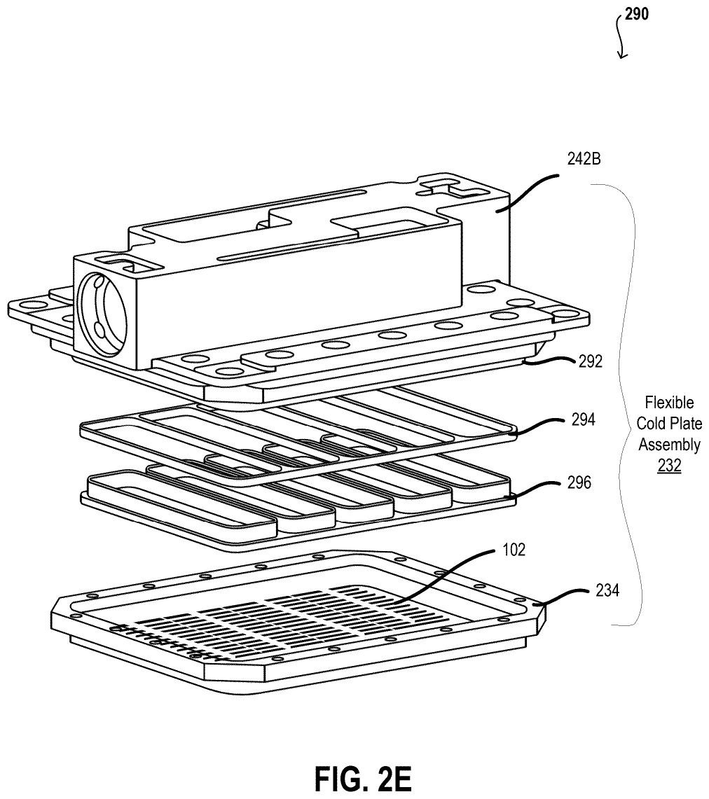

FIG. 1A is an illustration of a flexible cold plate 100 having heat removal surface extensions, discontinuities within the heat removal surface extensions, or one or more thin base plate, in at least one embodiment. The flexible cold plate 100 may be part of a flexible cold plate assembly (as in FIG. 2B) and may allow for conformance or flexing to support warping associated with an underlying computing component, as detailed further in connection with FIGS. 2B-5B. The conformance or flexing may be based, at least in part, on heat removal surface extensions 102 provided on a base plate 104 and having one or more of discontinuities 106 within the heat removal surface extensions 102 or a base plate 104 being thin.

The heat removal surface extensions 102 may be structures with heat removal channels there between. The heat removal channels may be for fluid or other media to enter from the cold plate distribution channels, to flow through, and to exit the heat removal channels to other cold plate distribution channels provided. For example, a flow of fluid or other media may enter 110A evenly across multiple ones of the cold plate distribution channels that may be inlet channels 110D. The inlet channels 110D may be a center channel and outer edge channels of the cold plate distribution channels, as illustrated. The flow may occur through the heat removal channels 110C (which may be microchannels that may not be fully illustrated and may not be to scale in FIG. 1A). The flow may exit 110B out of multiple ones of the cold plate distribution channels that may be outlet or exit channels 110E of the cold plate distribution channels, as illustrated. Further, FIG. 1A illustrates that flow through the heat removal channels 110C may be an even or uniform flow. FIG. 1A does not illustrate every inlet channels 110D, every outlet or exit channel 110E, every entry 110A flow, every exit 110B flow, or every heat removal channel 110C, but these are readily apparent to address cooling needs, and can be scaled up or down (more or less channels, entries, and exists), as required.

The discontinuities 106 may be cross-cuts on fins, in one example. The conformance or flexing may be based, at least in part, on the base plate 104 being thin, which, as used herein, may be so referenced at least in part for including a dimension or thickness 108 that is in the range of one of: 150 microns to 200 microns, 200 microns to 300 microns, 300 microns to 400 microns, or 400 microns to 500 microns.

In another example, the flexible cold plate assembly (such as in FIG. 2B) may include the flexible cold plate 100 which allows for conformance or flexing to support warping associated with an underlying computing component. The conformance or flexing may be based, at least in part, on heat removal surface extensions 102 provided over a base plate 104 having a dimension or thickness 108 of between 150 microns and 500 microns and is additionally based, at least in part, on the heat removal surface extensions having discontinuities 106 therein. The discontinuities may be perpendicular to a direction of the entry 11A flow and exit 110B flow, with respect to fluid or other media used for cooling the underlying computing component, through the heat removal surface extensions 102.

A flexible cold plate 100 may include a thin base plate 104 formed of copper or other suitable heat removal or transfer material, which may be also used for the heat removal surface extensions 102. As used herein, the heat removal surface extensions 102 may be provided of a same material or a different material, relative to the base plate 104, and may extend a surface area of the base plate 104 that is subject to heat removal. Therefore, the heat removal surface extensions 102 may be fins, including cylindrical fins, square fins, and other dimensional fins, or may include a roughness or other textured surface. When the heat removal surface extensions are fins, they may provide there between heat removal channels representing heat removal surface extensions, in at least one embodiment.

Further, the thin base plate herein may allow, in part, the flexible cold plate to be conformal or flexible. In one example, the flexible cold plate herein may be able to follow a dynamic curvature of an underlying computing component throughout its lifecycle (including both during usage and preparation stages and provide tolerance control. In one example, the flexible cold plate flexes with the changing component warpage as the component increases or decreases in warpage during cooling and heating cycles. The underlying computing component may be in reference to a circuit board, a central processing unit (CPU), a graphics processing unit (GPU), a data processing unit (DPU), quantum processing units (QPUs), a plurality of parallel processing units (PPUs), or other such component that may have active parts and passive or less active parts, where the passive or less active parts may be associated with a lower activity measure relative to at least one active part. For instance, a core of the GPU may be an active part, whereas buffer regions of the component may be a passive or less active part for the GPU.

QPUs may be configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU, with which the local qubits are associated.

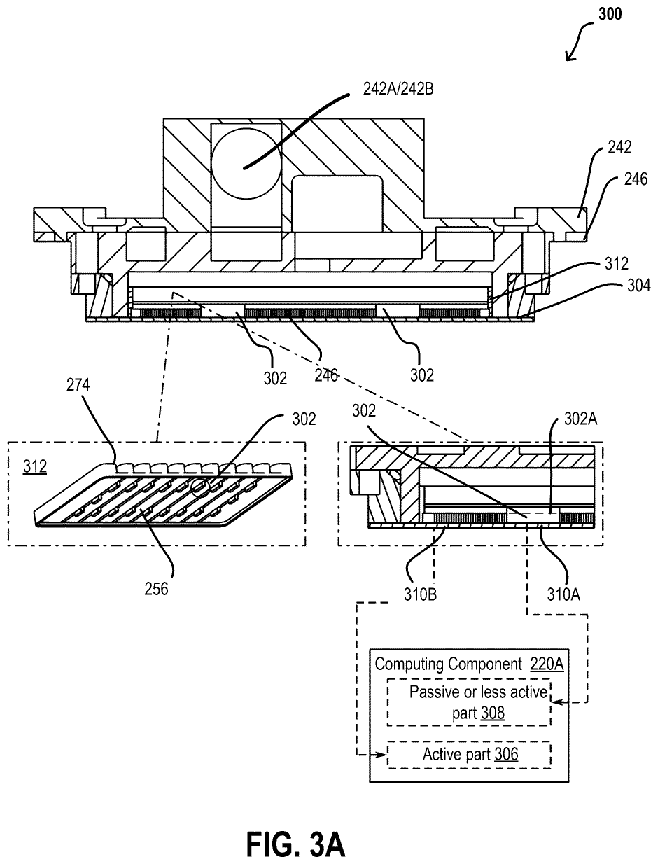

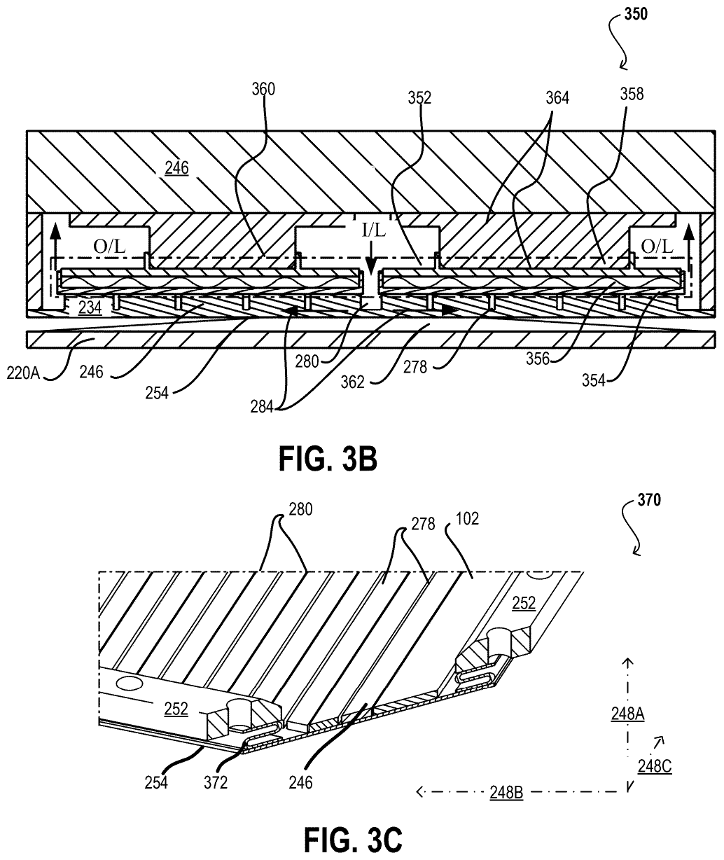

As the underlying computing component is subject to heating or cooling during or after performing of a workload, there may be a possibility for warping or the curvature to occur in a non-uniform manner. In addition to the base plate being thin, the flexible cold plate assembly may include the discontinuities within the heat removal surface extensions 102 to allow a degree of stress relief for the flexible cold plate assembly. The flexible cold plate assembly may also include a distribution seal (FIGS. 2B-3C). The distribution seal may have flexing or conformance properties and may include a material such as rubber (including ethylene propylene diene monomer rubber), silicone, or other suitable material (including elastomers) to allow a seal between the flexible cold plate and an overlying distribution manifold. The distribution seal may provide a sealing surface on the top of the heat removal surface extensions while allowing the heat removal surface extensions and the heat removal surface extensions to flex. In one example, a bottom side of the distribution seal may have a flat surface to sit flush and to provide a sealing surface on top of the heat removal surface extensions, as well as the discontinuities. At the same time, the flat surface allows fluid through intended paths of the heat removal surface extensions, without exiting the flexible cold plate, while supporting further conforming or flexing of the base plate in the flexible cold plate assembly.

In one instance, the flexible cold plate assembly may support a fluid or other media, such as a coolant, through a flow path formed from a manifold lid, a distribution manifold, a distribution seal, and the heat removal surface extensions. The heat removal surface extensions may be implemented using a manifold microchannel (MMC) approach that is apparent upon fully reviewing the disclosure herein. In operation, a fluid may enter the heat removal surface extensions vertically, from ports of a manifold lid to a distribution manifold and to the distribution seal (detailed further in FIGS. 2B-3C). The fluid may impinge on the base plate 104 of the heat removal surface extensions 102, may be caused to turn 90 degrees, and may be caused to travel along each of the heat removal surface extensions 102. The fluid may then turn another 90 degrees and may exit vertically from the heat removal surface extensions 102 of the flexible cold plate 100, through the distribution seal, the distribution manifold, and the distribution lid, to exit the flexible cold plate assembly.

A cross-section view and plan view of the flow path, the heat removal surface extensions 102 and the discontinuities 106 are detailed in the figures herein. The discontinuities 106 may be interspersed between inlet and outlet aspects of the heat removal surface extensions 102. The discontinuities 106, in addition to providing stress relief, may also break up a momentum and a thermal boundary layer of a flexible cold plate. This may support or lead to enhanced thermal performance in the flexible cold plate assembly. The distribution seal may be a flexible gasket or seal that can, in addition to providing a first seal for tops of the heat removal surface extensions using a flat bottom side, provide a second seal which is around vertical members or features forming manifold distribution channels in the distribution manifold using U-shaped features on a top side of the distribution seal. The second seal is to prevent fluid from crossing between inlet and outlet ports of the distribution manifold.

The second seal can prevent flow exchange (such as leakage) between inlet and outlet ports of the distribution manifold, in a similar manner as the first seal at the top of the heat removal surface extensions prevents fluid from crossing individual ones of the heat removal surface extensions. In addition, the distribution seal can flex with the underlying computing component while maintaining the seal at its top and bottom sides. Another aspect of the flexible cold plate assembly herein is an ability to restrict flow to less active parts of the underlying computing component using, at least in part, the distribution seal, as detailed with respect to at least FIG. 3A herein. For instance, the distribution seal may include the flow restrictors, which may be strategically located in between the heat removal surface extensions. Their placement may be predetermined based at least in part on layouts associated with the underlying computing component being cooled. The flexible cold plate assembly having such a distribution seal can prevent fluid from traveling over parts of a base plate of the flexible cold plate that are located over a passive or less active part of the underlying computing component. Still further, the flexible cold plate assembly herein may rely on a dual-plate distribution seal with a spring, such as a wave spring. The spring allows application of pressure on at least one plate that is movable, in relation to another plate that is stationary, and allows the dual-plate distribution seal to maintain at least the seal with respect to the tops of the heat removal surface extensions.

The flexible cold plate assembly herein can address component sizes that are increasing and that have large package sizes. A result of a large package size may be warpage of the package during use or when cooling of the component. The flexible cold plate assembly herein may be used in components that include liquid-cooled products in a server tray, a server rack, or other aspects of a datacenter, as described in connection with at least FIG. 1B. Instead of rigid and inflexible cold plates that may have a thickness of 1.25 millimeter or more, the flexible cold plate assembly herein is able to address warpage and provide further benefits of improved performance of the underlying computing component using one or more of a thin base plate, discontinuities, and a distribution seal capable of conforming or flexing. A consequence of rigid and inflexible cold plates may be that when such a cold plate is placed on top of a bare GPU die, forming a representative component to be cooled, such a cold plate may be high-centered and may have a minimal bond-line thickness at an apex of the component. Such a rigid and inflexible cold plate may also have a greater bond-line thickness at the edges of the component.

Warpage in a component and its associated package may change with operating temperature, where the package may be most warped at room temperature and may be least warped at operating temperature. A difference between a flattest and a most warped state may be measured in the range of several hundred microns. However, warpage may result in changing bond-lines, which can make thermal interface material (TIM) management challenging. Another challenge addressed by the flexible cold plate assembly herein is an issue posed by rapidly rising power consumption of a component, such as a GPU. The combination of increasing package sizes, increasing warpage, and increasing power consumption can be addressed by a high-performance copper-based flexible cold plate within the flexible cold plate assembly. The flexible cold plate assembly may be able to conform with the changing component warpage and may provide a high-performance bond whose integrity is maintained by the component warpage changes during operation.

FIG. 1B is an illustration of a datacenter 150 subject to a flexible cold plate assembly, in at least one embodiment. The datacenter 150 may be subject to a flexible cold plate assembly having heat removal surface extensions and discontinuities that are perpendicular to a direction of flow of a fluid through the heat removal surface extensions, as described in connection with FIG. 1A, along with distribution seals that support the flexible cold plate assembly, as described in connection with one or more of FIGS. 2A-3C. The datacenter 150 may be one or more rooms 152 having racks 160 and auxiliary equipment to house one or more servers on one or more server trays having circuit boards therein, which may be altogether referred to herein as computer modules. The datacenter 150 may be supported by a cooling tower 154 located external to the datacenter 150. The cooling tower 154 may dissipate heat from within the datacenter 150 by acting on a primary cooling loop 156. Further, a cooling distribution unit (CDU) 112 may be used between the primary cooling loop 156 and a secondary cooling loop 158 to allow extraction of the heat from the secondary cooling loop 158 to the primary cooling loop 156. The secondary cooling loop 158 can access various plumbing all the way into the server tray as required, in an aspect.

The primary and secondary cooling loops 156, 158 are illustrated as line drawings, but a person of ordinary skill would recognize that one or more plumbing features may be used. In an instance, flexible polyvinyl chloride (PVC) pipes may be used along with associated plumbing to move the media along in each of the primary and secondary cooling loops 156, 158. One or more pumps, in at least one embodiment, may be used to maintain pressure differences within the primary and secondary cooling loops 156, 158 to allow the movement of a media (such as a primary media or a secondary media that may be a coolant or refrigerant) according to temperature sensors in various locations, including in the room, in one or more racks 160, and/or in server boxes or server trays within the racks 160. As used herein, at least the secondary cooling loop 158, which is associated with a primary cooling loop 156, may be configured to cool computing components of the computer module using a flexible cold plate assembly having a distribution manifold with central fasteners and a stiffener frame with perimeter fasteners, as detailed further in one or more of FIGS. 2A-7 herein.

In at least one embodiment, a secondary media in a secondary cooling loop 158 have an inlet temperature of above 0 degrees centigrade (° C.) but less than 40° C., and may exit with a temperature of about 60° C. In one example, a primary media in the primary cooling loop 156 may be used to cool the secondary media in the secondary cooling loop 158. The primary media and the secondary media may be at least water and an additive, for instance, glycol or propylene glycol. In operation, each of the primary and the secondary cooling loops 156, 158 have their own media. In an aspect, the media in the secondary cooling loops may be proprietary to the requirements of the components in the server tray or racks 160.

The CDU 112 may be capable of sophisticated control of the primary and the secondary media, independently or concurrently, in the primary and the secondary cooling loops 156, 158. For instance, the CDU 112 may be adapted to control the flow rate of a secondary media of the secondary cooling loop 158 so that the secondary media may be appropriately distributed to extract heat generated within the racks 160. Further, more flexible rack manifold or tubing 114 is provided from the secondary cooling loop 158, relative to the primary cooling loop, to allow entry to each computer module and to provide secondary media to the computing components therein. In the present disclosure, the computing components may be used interchangeably to refer to the heat-generating components that benefit from the present datacenter cooling system.

The room manifold or tubing 118 illustrated in FIG. 1B and that may form part of the secondary cooling loop 158 may be referred to as room manifolds or room tubing. Separately, additional row manifold or tubing 116 extending from such room manifolds or tubing 118 may also be part of the secondary cooling loop 158 but may be referred to as row manifolds or row tubing. Still further, the rack manifold or tubing 114 illustrated in FIG. 1B may enter the racks as part of the secondary cooling loop 158, but may be referred to as rack cooling manifold. Further, the row manifolds or tubing 116 may extend to all racks along a row in the datacenter 150. The plumbing of the secondary cooling loop 158, including the room, row, or rack manifolds or tubing 118, 116, and 114 may be improved by at least one embodiment of the present disclosure. An optional chiller 120 may be provided in the primary cooling loop within datacenter 150 to support cooling before the cooling tower. To the extent additional loops exist in the primary control loop, a person of ordinary skill would recognize reading the present disclosure that the additional loops provide cooling external to the rack and external to the secondary cooling loop; and may be taken together with the primary cooling loop for this disclosure.

In at least one embodiment, in operation, heat generated within server trays of the racks 160 may be transferred from at least one cold plate to a media exiting the racks 160 via flexible tubing of the rack manifold or tubing 114 of the secondary cooling loop 158. In one example, secondary media (in the secondary cooling loop 158) from the CDU 112, for cooling the racks 160, moves towards the racks 160. The secondary media from the CDU 112 passes from one side of the room manifold or tubing 118, to one side of the rack 160 via row manifold or tubing 116, and through one side of the server tray via provided rack manifold or tubing 114. Spent secondary media (or exiting secondary media carrying the heat from the computing components) may exit out of another side of the server tray (such as entering the left side of the rack and exiting the right side of the rack for the server tray after looping through the server tray or through components on the server tray). The spent secondary media that exits the server tray or the rack 160 comes out of different side (such as exiting side) of rack manifold or tubing 114 and moves parallel, but also exiting side, row manifold or tubing 116. From the row manifold or tubing 116, the spent secondary media may move in a parallel portion of the room manifold or tubing 118 going in the opposite direction than the incoming secondary media (which may also be the renewed secondary media), and towards the CDU 112. Further, the spent secondary media may have an exit temperature of above 0° C. and may specifically be in a range which is between 40-60° C.

In at least one embodiment, the spent secondary media may exchange its heat with a primary media in the primary cooling loop 156 via the CDU 112. The spent secondary media may be renewed (such as relatively cooled when compared to the temperature at the spent second coolant stage) and ready to be cycled back through the secondary cooling loop 158 to the computing components or features. Various flow and temperature control features in the CDU 112 allow control of the heat exchanged from the spent secondary media or the flow of the secondary media in and out of the CDU 112. The CDU 112 is also able to control a flow of the primary media in primary cooling loop 156.

FIG. 2A is an illustration of computer module aspects 200 of a flexible cold plate assembly, in at least one embodiment. The computer module aspects 200 may include server-level features and may include a computer module 202 having at least one server manifold 204 to allow entry and egress of a cooling media of a secondary cooling loop 158, from a rack 160. However, the server manifold 204 may include separate channels for an inlet and for exit of media of the secondary cooling loop 158, which is illustrated as an extension from the rack to be secondary cooling loops 214A, 214B, within the computer module.

The secondary media may enter from a rack manifold, via inlet pipe 206 and may exit via outlet pipe 208. The secondary media, on the server side, may travel via inlet line 210, through one or more cold plates 210A, 210B, and via outlet line 212 to the manifold 204. This represents at least one or multiple secondary cooling loops 214A, 214B within the computer module 202 that may have a server tray or box form-factor. These multiple secondary cooling loops 214A, 214B may be an extension of the secondary cooling loop 158 interfacing with the primary cooling loop 156 as they provide the same or substantially the same secondary media from the secondary cooling loop 158 to the cold plates 210A-210D. In at least one embodiment, the cold plates 210A-210D are associated with at least one computing component or feature 220A-220D. In addition, while illustrated as different cold plates, the illustrated cold plates 210A-210D may be part of a large single cold plate structure and have integrated contact points that are specifically over the underlying computing components 220A-220D. A computing component 220A-220D may include processors, memories, and switches or regulators. In one example, the processors may include GPUs, CPUs, DPUs, PPUs, QPUs, and ASICs.

In at least one embodiment, even though illustrated as having one inlet and one outlet or exit for inlet line 210 and for outlet line 212, there may be multiple intermediate lines, such as flexible pipes associating the cold plate with the respective inlet line 210 and outlet line 212. In at least one embodiment, the intermediate lines directly couple the cold plate to the manifold 204 are provided inlet and outlets for such connections. In at least one embodiment, media adapters are provided to allow such coupling. In at least one embodiment, the media adapters are sized to the inlet and outlet provisions in the cold plate and the manifold 204.

FIG. 2A also illustrates that computer module aspects 200 may include a circuit board 222 having interconnect features 224 on a first side (top side, as illustrated) and on a second side (bottom side, similar features as the top side illustrated or soldered features relative to the top side). The interconnect features 224 may couple one or more of the computing components 220A-220D together. The interconnect features 224 may include copper traces, plated and non-plated through-holes, solder points, transmission lines, and electrically-insulating circuit board material over which such copper traces and solder points may lie.

In at least one implementation, a secondary cooling loop 158; 214A; 214B may be used to capture a largest portion of heat generated within the system, while targeting the computing components 220A-220D. For instance, it is possible to capture ambient heat that may be other than the targeted computing components 220A-220D. Therefore, it is possible to capture about 80-90% of heat generated from a computer module or a rack by one or more of the secondary cooling loops 158; 214A; 214B. This is even though the secondary cooling loop 158; 214A; 214B may operate at temperatures that are greater than 0° C. and even though the secondary cooling loop 158; 214A; 214B may operate using a water-based media. Any or all of the illustrated cold plates 210A-210D may be individual flexible cold plate assemblies over the underlying computing components or features 220A-220D.

FIG. 2B is an illustration of cross-section aspects 230 of a flexible cold plate assembly 232 that may be any of the cold plates 210A; 210B; 210C; 210D in FIG. 2A, in at least one embodiment. The cross-section aspects 230 are also in the form of an exploded view of the assembled version 232A of the flexible cold plate assembly 232, illustrated in FIG. 2B. The cross-section aspects 230 include a flexible cold plate 234 that may have heat removal surface extensions 102 and may have discontinuities within the heat removal surface extensions 102, as detailed further in connection with at least FIG. 2D herein. The flexible cold plate 234 may be like the flexible cold plate 100 in FIG. 1A or may include elevated boundary areas (detailed further in FIG. 2C). The discontinuities in the heat removal surface extensions 102 may be in a perpendicular direction or axis 248A relative to a direction or axis 248B of the heat removal surface extensions. The discontinuities can allow conformance or flexing in the flexible cold plate 234 to support warping associated with an underlying computing component 220A; 220B; 220C; 220D.

Further, the cross-section aspects 230 illustrate that a distribution seal 238 may be provided over the flexible cold plate 234. The distribution seal 238 can provide a seal at a first top of the heat removal surface extensions 102 and at a second top of the discontinuities, which is illustrated and detailed further in FIG. 2D. The distribution seal 238 may also be configured as a manifold for further conforming or flexing, relative to the conforming or flexing aspects provided by the flexible cold plate 234. For instance, the further conforming or flexing allows the distribution seal 238 to move with the flexible cold plate. Therefore, the further conforming or flexing may be with respect to conforming or flexing that occurs in the flexible cold plate, and may be with respect to warping that occurs or that is associated with the underlying computing component 220A; 220B; 220C; 220D. There may be at least one O-ring seal 236 between the distribution manifold 246 and flexible cold plate 234 to prevent fluid from exiting the flexible cold plate or the distribution manifold during use of the flexible cold plate assembly 232. Instead of an O-ring seal, there may be at least one of epoxy, adhesive, or a weld between the distribution manifold and flexible cold plate to prevent the fluid from exiting the flexible cold plate or the distribution manifold.

Further, as illustrated, the manifold lid 242 may be fastened to the distribution manifold 246 using fasteners 244, with the manifold lid 242 and the distribution manifold 246 positioned over the distribution seal 238. The fasteners 244 may be threaded and may also extend to the flexible cold plate 234 to provide stiffening in the flexible cold plate assembly 232. The manifold lid 242 may be used to guide fluid from a fluid inlet 242A of the manifold lid 242 to manifold distribution channels 240A of the distribution manifold 246. The manifold distribution channels 240A, in turn, allow the fluid to reach the heat removal surface extensions 102 of the flexible cold plate 234. The fluid may be returned from the heat removal surface extensions 102 to the manifold distribution channels 240A and to the manifold lid 242, prior to being removed from the flexible cold plate assembly 232 via a fluid outlet 242B. The fluid outlet 242B may be a structurally similar opening as the fluid inlet 242A and may be located on an opposite side of the manifold lid 242 relative to the fluid inlet 242A.

FIG. 2C is an illustration of further aspects 250 of a flexible cold plate assembly, in at least one embodiment. As illustrated, the flexible cold plate 234 may include a base plate 254 that may be a thin base of copper material. The flexible cold plate 234 may include elevated boundary areas 252 throughout a perimeter of the flexible cold plate assembly 232. The flexible cold plate 234 may include the heat removal surface extensions 102, which extends along a longer axis 248B of the flexible cold plate 234. Therefore, in FIG. 2C, front edges 258 of the heat removal surface extensions 102 may be visible in a cross-section that is perpendicular to the longer axis 248B and that is parallel to the shorter axis 248A of the flexible cold plate 234.

The thin and flexible base forming the base plate 254 allows for improved cooling of silicon features of the computing components by control of the bond-line thickness of the TIM and to achieve a uniform and controlled bond-line. In one example, the TIM achieved is a thin layer in the order of thickness that may be based at least in part on the thickness of the base plate 254. For example, the TIM is allowed to be a thin layer which is less than 100 microns in thickness. In another example, the TIM is a thin layer in the range of one of: less than 100 microns, 100 microns to 200 microns, 200 microns to 300 microns, 300 microns to 400 microns, or 400 microns to 500 microns.

FIG. 2C also illustrates the distribution seal 238 in a cross-section that is along the shorter axis 248A (as in FIG. 2B) of the flexible cold plate 234. The distribution seal 238 can provide a seal at a top of the heat removal surface extensions 102 at least by virtue of a flat surface on a bottom side 256 of the distribution seal 238 that sits flush against the tops of the heat removal surface extensions 102. This allows the distribution seal 238 to provide a seal at the tops of the heat removal surface extensions 102, to prevent fluid from crossing individual ones of the heat removal surface extensions 102.

The distribution manifold 246 can be over the distribution seal 238 and can include manifold distribution channels 240A to distribute fluid, received into the distribution manifold 246, to the heat removal surface extensions 102. For instance, the manifold distribution channels 240A may include ports 240B to distribute the fluid to at least the distribution seal. As detailed further in connection with at least FIG. 2D, the distribution seal 238 may have inlet (“I/L”) and outlet (“O/L”) ports for allowing the fluid from the distribution seal 238 to enter and exit the heat removal surface extensions 102.

FIG. 2D is an illustration of cross-sectional and plan view aspects 270 of heat removal surface extensions and cross-cuts that are perpendicular to a direction of flow of a fluid through the heat removal surface extensions in a flexible cold plate assembly, in at least one embodiment. The flexible cold plate 234 may include multiple cross-cuts 278 that may be within the heat removal surface extensions 102 to separate the heat removal surface extensions 102. The cross-cuts 278 may be along direction or an axis 248A which may be a shorter axis of the flexible cold plate 234 and may be perpendicular to a direction or an axis 248B of the heat removal surface extensions 102. The cross-cuts 278 may extend, in a vertical direction or axis 248C (also in FIG. 2B), from a top of the heat removal surface extensions 102 to the base plate 254 of the flexible cold plate 234. The cross-cuts 278 can allow conformance or flexing in the flexible cold plate 234 to support warping associated with an underlying computing component 220A-220D.

A distribution seal 238 may include U-shaped features 272 that are on a top side 274 of the distribution seal 238 and that is opposite to the bottom side 256 of the distribution seal 238. The U-shaped features 272 fit around posts 276 that form part of the manifold distribution channels 240A. The U-shaped features 272 can provide a further seal over at least part of the manifold distribution channels 240A to prevent fluid from crossing between inlet and outlet ports. This further seal is different than the seal provided using the flat surface on the bottom side 256 of the distribution seal 238, where the flat surface is at the top of the heat removal surface extensions 102 and at the top of the cross-cuts 278. The distribution manifold 102 has its manifold distribution channels 240A aligned with distribution seal channels 282 of the distribution seal 238. In turn, the distribution seal channels 282 are aligned with cold plate distribution channels 280 (also 110D, 110E) of the flexible cold plate 234. The manifold distribution channels 240A, the distribution seal channels 282, and the cold plate distribution channels 280 may individually include alternating inlet (cold) or outlet (hot) channels. This allows fluid that is in a cold state, relative to at least a temperature of the underlying computing component (or to active parts of the underlying computing component), to be received (“X” annotations in FIG. 2D) into the heat removal surface extensions 102 and to exit (“O” annotations in FIG. 2D) from the heat removal surface extensions 102 through different paths.

The fluid flows along the illustrated paths 284 of the heat removal surface extensions 102 after entering into the cold plate distribution channels 280, from the inlet to the outlet within each of the channels, 240A, 282, and 280. As the tops of the heat removal surface extensions 102 and the cross-cuts 278 are sealed by at least the bottom side 256 of the distribution seal 238, the fluid is ensured to be within the paths 284 provided. The distribution seal 238 is configured for further conforming or flexing, with respect to the flexible cold plate, upon warping associated with the underlying computing component. For instance, the distribution seal 238 is a rubber or other gasket material and is capable of conforming or flexing by the nature of the rubber or other gasket material. Further, the distribution seal 238 can slide relative to the distribution manifold 246 as needed, upon displacement caused in part by the base plate 254 upon warping associated with the underlying computing component 220A and to be conforming or flexing to the warping.

FIG. 2E is an illustration of cross-sectional view aspects 290 of a distribution seal having a top distribution seal portion and a bottom distribution seal portion, in at least one embodiment. The cross-sectional view aspects 290 include, in a manner similar to FIG. 2B, a manifold lid 242 that may be fastened to a distribution manifold 292. The distribution manifold 292 may have slightly different distribution manifold channels to align with a distribution seal 294, 296 provided in two portions and provided with bridging therebetween instead of having a perimeter seal as illustrated in FIG. 2B. Fasteners may be used between the manifold lid 242 and the distribution manifold 292 positioned over the distribution seal 294 296. The fasteners may also extend to the flexible cold plate 234 to provide stiffening in the flexible cold plate assembly 232. The manifold lid 242 may be used to guide fluid from a fluid inlet of the manifold lid 242 to manifold distribution channels of the distribution manifold 292. The manifold distribution channels, in turn, allow the fluid to reach the heat removal surface extensions 102 of the flexible cold plate 234 that may have a slightly different structure to support the distribution seal in portions, but that may have one or more of at least the discontinuities or the thin base plate. A top distribution seal portion 294 and a bottom distribution seal portion 296 may be provided. The bottom distribution seal portion 296 may be provided to allow the seal at the first top of the heat removal surface extensions and the second top of the discontinuities. The top seal distribution portion 294 may provide a further seal between the distribution manifold 292 and the bottom distribution seal portion 296.

FIG. 3A is an illustration of a flexible cold plate assembly 300 with a distribution seal having flow restrictions to block or limit fluid from reaching portions of the flexible cold plate in a flexible cold plate assembly, in at least one embodiment. The distribution seal 312, in one embodiment, may include the illustrated flow restrictions 302 to block or limit fluid that enter the cold plate distribution channels 280 from reaching portions 310A of the flexible cold plate 304 associated with a passive or less active part 308 of the underlying computing component 220A. In at least one embodiment, the flow restrictions 302 may be extensions of the distribution seal 312. However, in at least one embodiment, the flow restrictions 302 may not be an extension and may remain a flat surface 302A that is even along with portions of the distribution seal 312 that are only at the tops of the heat removal surface extensions 102. In addition, the flow restrictions 302 may be extensions that may be partly within the gaps of the heat removal surface extensions 102. However, providing the flow restrictions 302 fully in the gaps, in one example, may be so that fluid pockets are not formed. The partial or flat surface 302A may be used to allow slower than usual flow (limited flow) through portions 310A of the flexible cold plate 304 associated with a passive or less active part 308 of the underlying computing component 220A.

The passive or less active part 308 may be associated with a lower activity measure relative to at least one active part 306 of the underlying computing component 220A, which may receive cooling for being under a portion 310B of the flexible cold plate 304 that has no blocking or limitation to the fluid. Therefore, the distribution seal 312 may be different or may include additional features (such as the flow restrictions 302), relative to the distribution seal 238 in FIGS. 2B-2D herein. Similarly, the flexible cold plate 304 may be different or may include additional features (such as spacing in one or more of the heat removal surface extensions, the cold plate distribution channels, or the cross-cuts to allow flow restrictions 302), relative to the flexible cold plate 234 in FIGS. 2B-2D herein.

FIG. 3B is a detailed illustration of a flexible cold plate assembly 350 with a distribution seal having a spring between a top plate and a bottom plate to perform further conforming or flexing in the distribution seal of a flexible cold plate assembly, in at least one embodiment. In FIG. 3B, it is apparent that reference to heat removal surface extensions 102 is to separations not illustrated that may be fins or other types of heat removal surface extensions. Similarly, the distribution manifold 246 is not generally illustrated and includes distribution channels, even if not illustrated in this figure, it is apparent from the descriptions and illustrates throughout herein. The flexible cold plate assembly 350 may include a different distribution seal 360 or further features in a distribution seal, relative to the distribution seal 238 in FIGS. 2B-2D herein. For instance, the distribution seal 360 may include a top plate 358 and a bottom plate 354. At least the bottom plate 354 can allow a seal at the first top of the heat removal surface extensions 102 and at the second top of the cross-cuts 278. The top plate 358 and the bottom plate 354 may support the cold plate distribution channels inlet (I/L) and outlet (O/L) 280 for fluid through the distribution manifold 246. For instance, the top plate 358 can provide a distribution channel seal, using its top side 352 which is against the distribution seal channels 282 of the distribution manifold 246. In turn, the cold plate distribution channels I/L and O/L 280 support flow through paths 284, along the heat removal surface extensions 102, as described in connection with at least FIG. 2D herein.

There may be a spring 356 provided between the top plate 358 and the bottom plate 354. The spring can allow one or more of the top plate 358 and the bottom plate 354 to perform a further conforming or flexing in the distribution seal 360, with respect to the flexible cold plate 234, upon warping 362 associated with the underlying computing component 220A. In one example, the bottom plate 354 may be configured to move along a vertical direction or axis 248C to be closer or farther with respect to the top plate 358, as part of the further conforming or flexing in the distribution seal 360. Alternatively, instead of movement, one or more of the top plate 358 and the bottom plate 354 may only flex, as assisted by the spring 356. As such, the spring may be formed from steel, copper, or other suitable material capable of spring-like action. In at least one embodiment, the top plate 358 and the distribution manifold 246 may be part of stationary structures 364 and the flex or movement may be only in the bottom plate 354.

Further, in assembly methodology, diffusion bonding may be performed for bonding together similar materials while leaving certain dissimilar materials as intended within the assembly. For instance, a temperature of the similar materials may be raised as close to a melting point for the similar materials to provide bonding. Such an approach may be used to bond, for instance, a top plate to the distribution channels, while allowing the bottom plate to be unbonded with respect to the heat removal surface extensions. This leaves the bottom plate with a conforming or flexing capability even if it seals the tops of the heat removal surface extensions. Therefore, the bottom plate, the top plate, and the heat removal surface extensions may be provided with different materials so that they do not bond in a diffusion bonding process. Meanwhile, the distribution channels may be of similar materials as the top plate so that these neighboring materials may be subject to a diffusion bond. Therefore, it is possible to cause diffusion bonding to occur at some part of a distribution seal as against other parts that are able to conform or flex with respect to the bonded parts. For instance, diffusion bonding may be used to bond the flexible metal bellow 372 to the base plate 254 and to the elevated boundary areas 252. Separately, brazing and laser welding are other options to provide one or more of the bonding aspects described throughout herein.

FIG. 3C is an illustration of features 370 to provide conformance or flexing in boundary areas of a flexible cold plate, in at least one embodiment. While at least in FIG. 2C, the flexible cold plate 234 may have elevated boundary areas 252, a thin base plate 254 of the bottom of the flexible cold plate 234 having the heat removal surface extensions 102, the cold plate distribution channels I/L and O/L 280, and the cross-cuts 278 may incorporate sufficient conformance or flexibility to any warping or non-flat silicon features in a center of the underlying computing component. However, there may be resulting stress on a perimeter of the flexible cold plate assembly 232. This may be at least because the elevated boundary areas 252 may not be able to conform or flex due to bonding to ridged components needed to complete the flexible cold plate assembly 232. The existence of internal fluid pressures may exacerbate this resulting stress.

In at least one embodiment, as in FIG. 3C, a flexible metal bellow 372 may extend throughout the perimeter of the flexible cold plate assembly 232. The flexible metal bellow 372 may be an S or other serpentine shaped feature to provide a mechanical connection that can create a robust fluid seal joining the elevated boundary areas 252 to the base plate 254 (or joining different layers of at least the perimeter of the flexible cold plate assembly 232). The flexible metal bellow 372 can also distribute any deflection and stress for all the different internal and external loads experienced in the flexible cold plate assembly 232. When the flexible metal bellow 372 is provided in a flexible cold plate assembly 232, the elevated boundary areas 252 may be such that it acts as a stiffener for the flexible cold plate assembly 232.

In at least one embodiment, the flexible cold plate assembly herein may include a flexible cold plate which allows for conformance or flexing to support warping associated with an underlying computing component. The conformance or flexing may be based, at least in part, on heat removal surface extensions provided over a base plate having a thickness that is preferably within a range which is between one of 150 to 200 microns, 200 to 300 microns, 300 to 400 microns, or 400 to 500 microns, wherein each of such ranges represent a thin base plate discussed throughout herein. The lower end of such ranges may present lesser reliance on cross-cuts, in at least one example. The lower end of such ranges may also present lesser reliance on a distribution seal having a flexing or conformance to a degree, in another example. In at least one embodiment, the conformance or flexing to support warping associated with a computing component may be based, at least in part, on heat removal surface extensions provided over a base plate having a thickness of between 150 microns and 500 microns, may be additionally based, at least in part, on the heat removal surface extensions having cross-cuts therein, wherein the cross-cuts are perpendicular to a direction of flow of a fluid through the heat removal surface extensions, and may be additionally based, at least in part, on the distribution seal having further conformance or flexibility by a material used in the distribution seal.

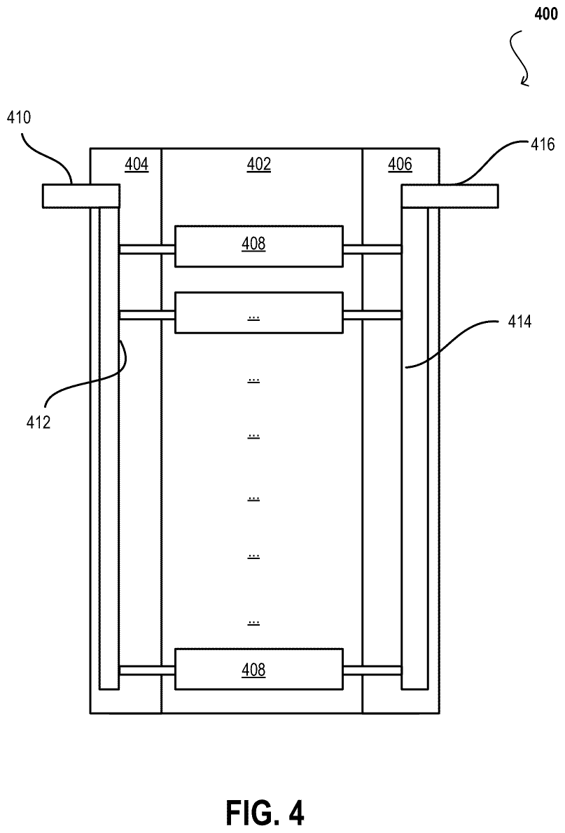

FIG. 4 illustrates rack aspects 400 in a system subject to a flexible cold plate assembly, according to at least one embodiment. A rack 402 has brackets 404, 406, to allow hanging of one or more cooling loop components within the rack 402. In at least one embodiment, rack manifolds 412, 414 may be provided to guide media from row manifolds to the computer modules 408 with the rack 402. The entry rack manifold 412 may pass media of a secondary cooling loop from the row manifolds through conduit 410, through the computer modules 408 that may be in a server tray or box form-factor, out of the egress rack manifold 414, and back into the row manifold via the egress conduit 416. The flexible cold plate assemblies herein may be used in any of the illustrated server tray or box forming the computer modules 408 and may also benefit from additional local distribution units if there is a need to increase pressure of media flow at any level of a rack.

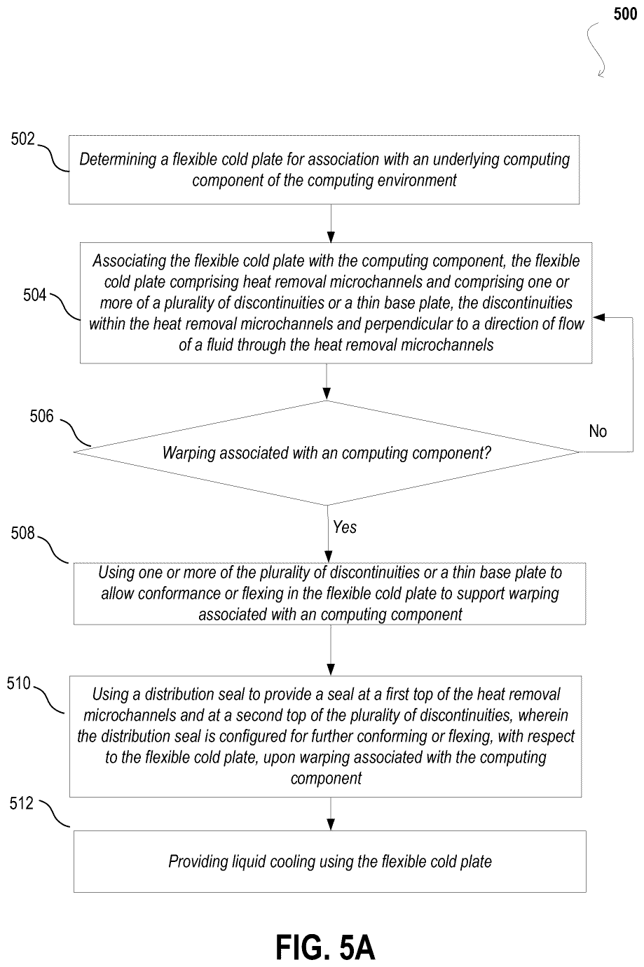

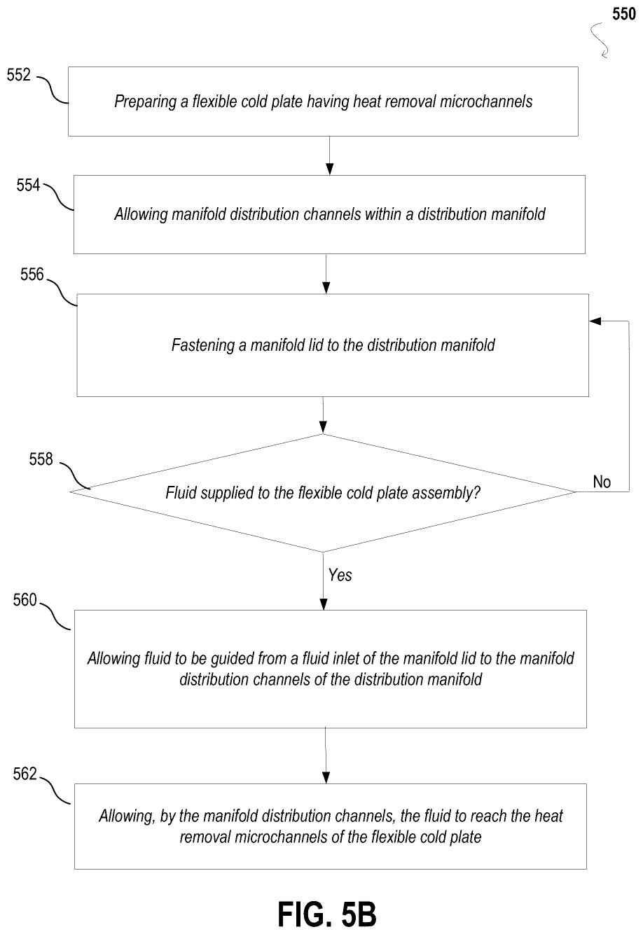

FIG. 5A illustrates a process flow or method 500 for a system having at least one flexible cold plate assembly, in at least one embodiment. The method 500 may include determining 502 a flexible cold plate for association with an underlying computing component of the computing environment. The determining 502 herein may take into account layouts (or design) of the underlying computing component, including its active and less active or passive parts. The determining 502 may also take into account an amount of flexing or conforming required or an amount of warping that may be caused in the underlying computing components. The determining 502 may also take into account temperatures associated with the underlying computing component and the fluid to be used in a liquid cooling system to be associated with the flexible cold plate.

The method 500 may include associating 504 the flexible cold plate with the underlying computing component. The flexible cold plate may include heat removal surface extensions and may include one or more of discontinuities, such as cross-cuts within the heat removal surface extensions, or a thin base plate. The discontinuities in the heat removal surface extensions may be perpendicular to a direction of flow of a fluid through the heat removal surface extensions. The method 500 may include determining or verifying 506 warping associated with an underlying computing component. This may be in support of the determining 502 step, in one example. The method 500 may include using 508 one or more of the discontinuities or the thin base plate to allow conformance or flexing in the flexible cold plate to support warping associated with an underlying computing component. For instance, a predetermined number of discontinuities may be associated with a measure of the warping expected in the underlying computing component or may be based in part on a size of the underlying computing component.

The method 500 may include using 510 a distribution seal to provide a seal at a first top of the heat removal surface extensions and at a second top of the plurality of discontinuities. The distribution seal may be configured for further conforming or flexing, with respect to the flexible cold plate, upon warping associated with the underlying computing component. The method 500 may include providing 512 the liquid cooling using the flexible cold plate and using fluid that may be predetermined for cooling the underlying computing component upon generation of heat during performing of a workload. In one example, the fluid may be provided at all times, irrespective of the heat generated or the workload being performed.

FIG. 5B illustrates yet another process flow or method 550 for a system having at least one flexible cold plate assembly, in at least one embodiment. The method 550 of FIG. 5B may be used alone or in combination with the method 500 of FIG. 5A by detailing further steps or sub-steps for the method 500 in FIG. 5A. The method 550 may include preparing 552 a flexible cold plate having heat removal surface extensions. The step of preparing 552 may include determining, machining, and designing the flexible cold plate to suit an application within an underlying computing component.

The method 550 may include allowing 554 manifold distribution channels within the distribution manifold. The step of allowing 554 such manifold distribution channels may include a preparing step in the manner of the preparing step 552 of the flexible cold plate and may also include sub-steps or steps for determining, machining, and designing of the distribution manifold to include the manifold distribution channels. In one example, the distribution manifold has to align with the flexible cold plate and, therefore, it is apparent that one or more steps in the methods 500, 550 of FIGS. 5A, 5B may be performed in a different order or by interchanging or repeating steps within the generally provided method steps.

The method 550 may include fastening 556 a manifold lid to the distribution manifold. This or any of such steps in the methods herein may include verification or determining that proper O-ring seals are put in place before one or more fastening or attaching steps are performed. The method 550 may include determining or verifying 558 that fluid is supplied to the flexible cold plate assembly. The flexible cold plate assembly incorporating at least steps 552-554 supports allowing 560 fluid to flow from a fluid inlet of the manifold lid, through one or more ports of a distribution manifold that is between the manifold lid and the distribution seal, and through the manifold distribution channels, the distribution seal channels, and the cold plate distribution channels. The flexible cold plate assembly incorporating at least steps 552-554 also supports allowing 560 fluid to be guided from a fluid inlet of the manifold lid to the manifold distribution channels of the distribution manifold. The method 550 may include allowing 562, by the manifold distribution channels, the fluid to reach the heat removal surface extensions of the flexible cold plate.

The method 500; 550 herein may include a step or sub-steps for providing a distribution manifold to be over the distribution seal and having therein manifold distribution channels. The method may include allowing U-shaped features on a top side of the distribution seal to provide a further seal over at least part of the manifold distribution channels. The method may include allowing a flat surface on a bottom side of the distribution seal to provide the seal at the first top of the heat removal surface extensions and the second top of the plurality of cross-cuts. The method may include using the distribution manifold to distribute fluid through the distribution seal and into the heat removal surface extensions, in support of steps 512 and 562 of the method or methods herein.

The method 500; 550 herein may incorporate a step of using at least one O-ring seal between the distribution manifold and flexible cold plate to prevent fluid from exiting the flexible cold plate or the distribution manifold. The method 500; 550 herein may include steps or sub-steps for fastening a manifold lid to a distribution manifold and over the distribution seal, and for allowing fluid to be guided from a fluid inlet of the manifold lid to manifold distribution channels of the distribution manifold. The manifold distribution channels can allow the fluid to reach the heat removal surface extensions of the flexible cold plate. The method 500; 550 herein may include a step or sub-steps for determining portions of the flexible cold plate that are associated with a passive or less active part of the underlying computing component. The passive or less active part may be associated with a lower activity measure relative to at least one active part of the underlying computing component. The method 500; 550 herein may include a step or sub-steps for allowing flow restrictions in the distribution seal to block or limit fluid from reaching portions of the flexible cold plate associated with the passive or less active part of the underlying computing component.

The method 500; 550 herein may incorporate a step for allowing the distribution seal to include a top plate, a bottom plate, and a spring which is between the top plate and the bottom plate. The method 500; 550 herein may incorporate a step for allowing the bottom plate for the seal at the first top of the heat removal surface extensions and at the second top of the plurality of cross-cuts. The method herein may include allowing, using the spring, one or more of the top plate and the bottom plate to perform the further conforming or flexing in the distribution seal, with respect to the flexible cold plate, upon warping associated with the underlying computing component. Further, the method 500; 550 herein may be such that the bottom plate is configured to vertically move closer or farther with respect to the top plate, as part of the further conforming or flexing in the distribution seal.

A flexible cold plate herein may include adjustable fins forming microchannels for fluid to flow through. In at least one embodiment, fins in a cold plate enable transfer of heat from at least one associated computing component to a fluid flowing through microchannels formed between multiple fins. In at least one embodiment, fins of a cold plate are dynamically and adjustable in real time to allow transfer of more heat from at least one computing component to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing component, a workload of at least one computing component, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

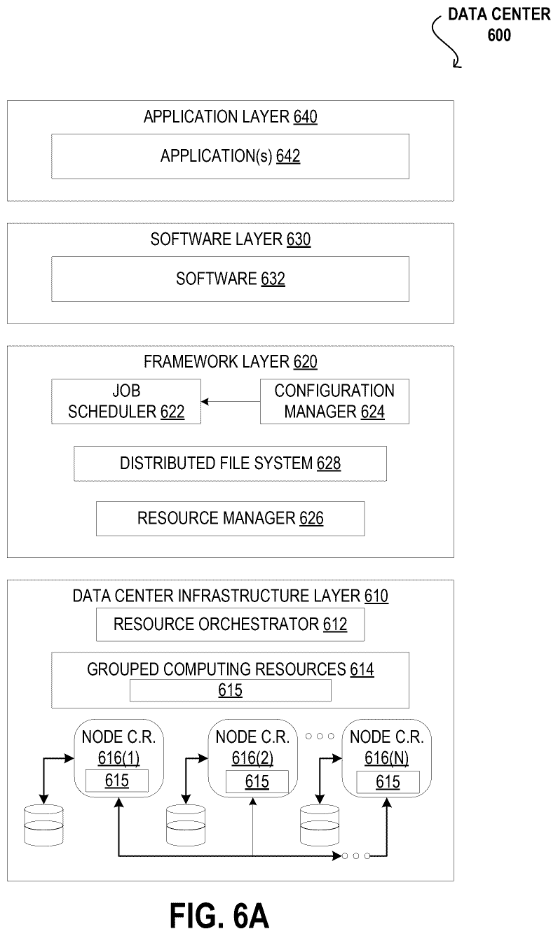

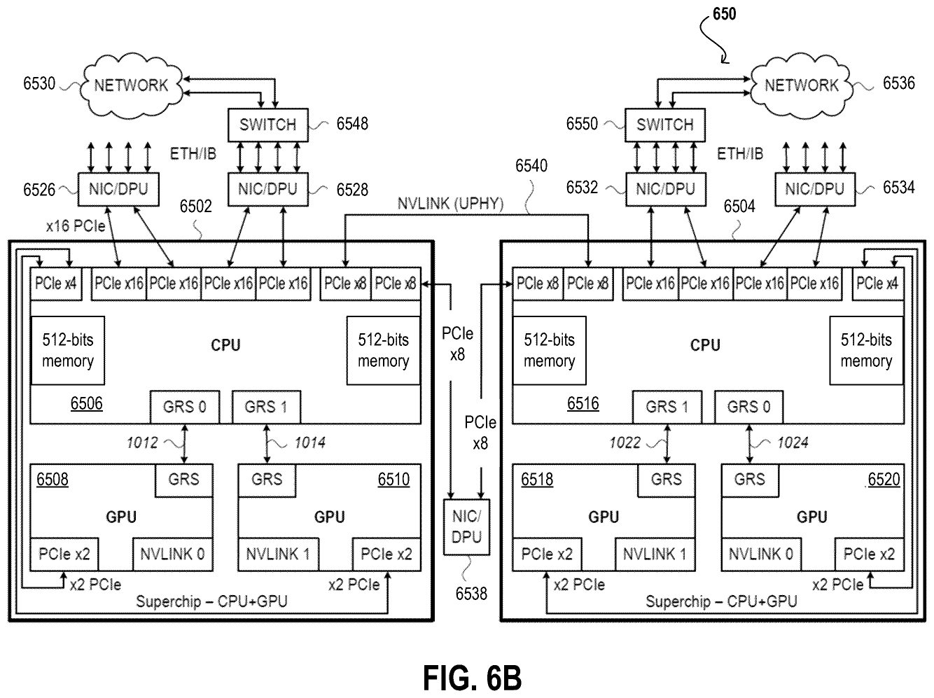

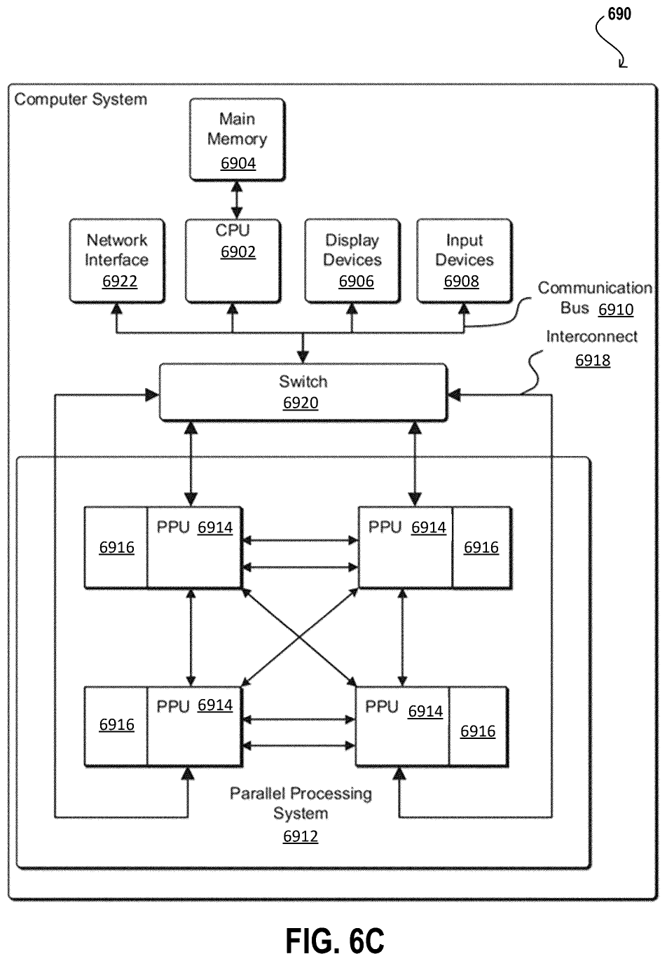

FIG. 6A illustrates an example datacenter 600, in which at least one embodiment from FIGS. 2A-5B may be used. For instance, the example datacenter 600 may be used to support one or more of the preparing or allowing steps to be used to generate or provide a flexible cold plate assembly for at least one underlying computing component of the example datacenter 600. However, the datacenter 600 may also include computer modules subject to a flexible cold plate assembly having cross-cuts and a flexing or conforming distribution seal associated therewith, in at least one embodiment, as described with respect to FIGS. 1A-5B herein.

In at least one embodiment, datacenter 600 includes a datacenter infrastructure layer 610, a framework layer 620, a software layer 630, and an application layer 640. In at least one embodiment, such as described in respect to FIGS. 1A-5B, features of the flexible cold plate assembly may be performed inside or in collaboration with the example datacenter 600. Also, features to generate or provide a flexible cold plate assembly for at least one underlying computing component may be performed inside or in collaboration with the example datacenter 600. In at least one embodiment, the infrastructure layer 610, the framework layer 620, the software layer 630, and the application layer 640 may be partly or fully provided via computing components on server trays located in racks 160 of the datacenter 150. This allows cooling systems of the present disclosure to direct cooling to certain ones of the computing components in an efficient and effective manner. Further, aspects of the datacenter, including the datacenter infrastructure layer 610, the framework layer 620, the software layer 630, and the application layer 640 may be used to support selection or design for a flexible cold plate assembly as discussed herein with at least reference to FIGS. 1A-5B above. As such, the discussion in reference to FIG. 6A may be understood to apply to the hardware and software features required to allow or support provision of a flexible cold plate, for instance.

In at least one embodiment, as in FIG. 6A, a datacenter infrastructure layer 610 may include a resource orchestrator 612, grouped computing resources 614, and node computing resources (“node C.R.s”) 616(1)-616(N), where “N” represents any whole, positive integer. In at least one embodiment, node C.R.s 616(1)-616(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources 614 may include separate groupings of node C.R.s housed within one or more racks (not shown), or many racks housed in datacenters at various geographical locations (also not shown). Separate groupings of node C.R.s within grouped computing resources 614 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator may include hardware, software or some combination thereof.

In at least one embodiment, as shown in FIG. 6A, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark™ (hereinafter “Spark”) that may utilize distributed file system 628 for large-scale data processing (such as “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resource 614 at datacenter infrastructure layer 610. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. One or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underutilized and/or poor performing portions of a datacenter.

In at least one embodiment, datacenter 600 may include tools, services, software or other resources to train one or more machine learning models or predict or infer information using one or more machine learning models according to one or more embodiments described herein. In at least one embodiment, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein. Deep learning may be advanced using any appropriate learning network and the computing capabilities of the datacenter 600. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 600 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as pressure, flow rates, temperature, and location information, or other artificial intelligence services.

Inference and/or training logic 615 may be used to perform inferencing and/or training operations associated with one or more embodiments. In at least one embodiment, inference and/or training logic 615 may be used in system FIG. 6A for inferencing or predicting operations based, at least in part, on weight parameters calculated using neural network training operations, neural network functions and/or architectures, or neural network use cases described herein. In at least one embodiment, inference and/or training logic 615 may include, without limitation, hardware logic in which computational resources are dedicated or otherwise exclusively used in conjunction with weight values or other information corresponding to one or more layers of neurons within a neural network. In at least one embodiment, inference and/or training logic 615 may be used in conjunction with an application-specific integrated circuit (ASIC), such as Tensorflow® Processing Unit from Google, an inference processing unit (IPU) from Graphcore™, or a Nervana® (such as “Lake Crest”) processor from Intel Corp.

In at least one embodiment, inference and/or training logic 615 may be used in conjunction with central processing unit (CPU) hardware, graphics processing unit (GPU) hardware or other hardware, such as field programmable gate arrays (FPGAs). In at least one embodiment, inference and/or training logic 615 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 615.

In at least one embodiment, therefore, the datacenter 600 supports a silicon package having a component to perform a workload and associated with a cold plate assembly. The silicon package can be part of the component or can include a computing component of the component described throughout herein in FIGS. 1A-5B. The cold plate assembly may be as detailed in connection with one or more of FIGS. 1A-5B herein. The cold plate assembly may include a flexible cold plate which allows for conformance or flexing to support warping associated with the silicon package. The conformance or flexing may be based, at least in part, on heat removal surface extensions having cross-cuts therein. The cross-cuts may be provided perpendicular to a direction of flow of a fluid through the heat removal surface extensions.

In at least one embodiment, therefore, the datacenter 600 herein may also include one or more racks comprising one or more server trays and may include one or more components in the one or more racks, where the one or more components are to perform at least part of a workload in the datacenter. Individual ones of the components may be associated with a cold plate assembly. The cold plate assembly may include a flexible cold plate which allows for conformance or flexing to support warping associated with one or more components. The conformance or flexing may be based, at least in part, on heat removal surface extensions having cross-cuts therein. The cross-cuts may be perpendicular to a direction of flow of a fluid through the heat removal surface extensions.

FIG. 6B is a block diagram that schematically illustrates a computing system that may be a data center or a High-Performance Computing (HPC) cluster, in which at least one embodiment from FIGS. 1A-5B may be used. The computing system 650 may include a plurality of subsystems, e.g. multiple processing devices coupled to each other, multiple network devices, and multiple networks, according to at least one embodiment. The computing system 650 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 650 and to one or more external networks 6530, 6536. In the present example, system 650 comprises a packet switch 6548 that connects NIC/DPU 6528 to network 6530, and a packet switch 6550 that connects NIC/DPU 6532 to network 6536.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 650 can include one or more CPUs and one or more GPUs.

FIG. 6B also demonstrates an example architecture of a multi-GPU architecture. As illustrated in the figure, computing system 650 includes a processing device 6502 with a multi-GPU architecture. In particular, processing device 6502 may be a system-on-chip and includes multiple subsystems such as a CPU 6506, a GPU 6508, and a GPU 6510. CPU 6506 can be coupled to GPU 6508 via a die-to-die (D2D) or chip-to-chip (C2C) interconnect 6512, such as a Ground-Referenced Signaling interconnect (GRS interconnect). CPU 6506 can be coupled to GPU 6510 via a D2D or C2C interconnect 6514. CPU 6506 can also couple to GPU 6508 and GPU 6510 via PCIe interconnects.

CPU 6506 can be coupled to one or more NICs or DPUs, which are coupled to one or more networks. For example, as illustrated in FIG. 6B, CPU 6506 is coupled to a first NIC/DPU 6526, which is coupled to a network 6530. CPU 6506 is also coupled to a second NIC/DPU 6528, which is coupled to network 6530 via switch 6548. NIC/DPU 6526 and NIC/DPU 6528 can be coupled to network 6530 over Ethernet (ETH), NVLINK or InfiniBand (IB) connections, for example.

Computing system 650 also includes a processing device 6504 with a multi-GPU architecture. In particular, processing device 6504 includes multiple subsystems including a CPU 6516, a GPU 6518, and a GPU 6520. CPU 6516 can be coupled to GPU 6518 via an D2D or C2C interconnect 6522. CPU 6516 can be coupled to GPU 6520 via a D2D or C2C interconnect 6524. CPU 6516 can also couple to GPU 6518 and GPU 6520 via PCIe interconnects. CPU 6516 can be coupled to one or more NICs or DPUs, which are coupled to one or more networks. For example, as illustrated in FIG. 6B, CPU 6516 is coupled to a first NIC/DPU 6532, which is coupled to a network 6536. CPU 6516 is also coupled to a second NIC/DPU 6534, which is coupled to network 6536 via switch 6550. NIC/DPU 6532 and NIC/DPU 6534 can be coupled to network 6536 over Ethernet (ETH), NVLINK or InfiniBand (IB) connections.

In at least one embodiment, processing device 6502 and processing device 6504 can communication with each other via a NIC/DPU 6538, such as over PCIe interconnects. Processing device 6502 and processing device 6504 can also communicate with each other over a high-bandwidth communication interconnects 6540, such as an NVLink interconnect or other high-speed interconnects. The packet switches in FIG. 6B may comprise, for example, Nvidia Quantum-2 switches. The NICs/DPUs in the figure may comprise, for example, Nvidia Bluefield DPUs.

In various embodiments, any of the network devices of the computing system 650, e.g., any of NICs/DPUs 6526, 6528, 6532, 6534 and 6538, and/or any of switches 6548 and 6550, may include a shaped leak sensor that can match a geometry around components and features in the computing system 650 and that can be communicatively coupled together to extend leak detection capabilities.

FIG. 6C illustrates a computer system, according to at least one example, in which at least one embodiment from FIGS. 1A-5B may be used. In at least one embodiment, computer system 690 is configured to implement various processes and methods described throughout this disclosure.

In at least one embodiment, computer system 690 comprises, without limitation, at least one central processing unit (“CPU”) 6902 that is connected to a communication bus 6910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 690 includes, without limitation, a main memory 6904 and control logic (e.g., implemented as hardware, software, or a combination thereof) and data are stored in main memory 6904 which may take form of random access memory (“RAM”). In at least one embodiment, a network interface subsystem (“network interface”) 6922 provides an interface to other computing devices and networks for receiving data from and transmitting data to other systems from computer system 690.

In at least one embodiment, computer system 690, in at least one embodiment, includes, without limitation, input devices 6908, parallel processing system 6912, and display devices 6906 which can be implemented using a conventional cathode ray tube (“CRT”), liquid crystal display (“LCD”), light emitting diode (“LED”), plasma display, or other suitable display technologies. In at least one embodiment, user input is received from input devices 6908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 6904 and/or secondary storage. Computer programs, if executed by one or more processors, enable system 690 to perform various functions in accordance with at least one embodiment. memory 6904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 6902; parallel processing system 6912; an integrated circuit capable of at least a portion of capabilities of both CPU 6902; parallel processing system 6912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 690 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 6912 includes, without limitation, a plurality of parallel processing units (“PPUs”) 6914 and associated memories 6916. In at least one embodiment, PPUs 6914 are connected to a host processor or other peripheral devices via an interconnect 6918 and a switch 6920 or multiplexer. In at least one embodiment, parallel processing system 6912 distributes computational tasks across PPUs 6914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 6914, although such shared memory may incur performance penalties relative to use of local memory and registers resident to a PPU 6914. In at least one embodiment, operation of PPUs 6914 is synchronized through use of a command such as_syncthreads( ), wherein all threads in a block (e.g., executed across multiple PPUs 6914) to reach a certain point of execution of code before proceeding.

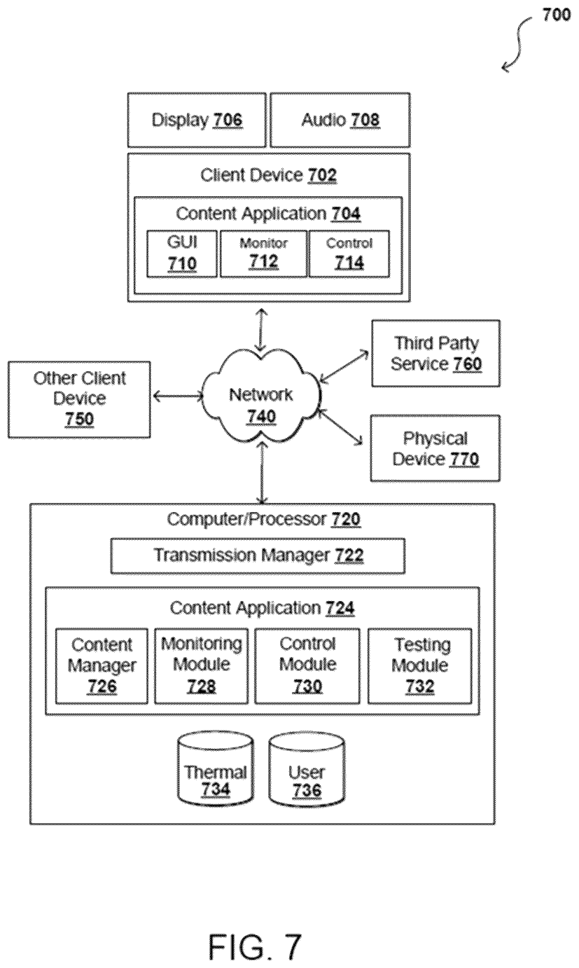

FIG. 7 illustrates an example network configuration 700 of components that can be used to implement aspects of various embodiments, such as to provide, generate, modify, encode, process, fuse, and/or transmit generated image data, calculated measurements, or other such content. In at least one embodiment, a client device 702 can generate or receive data for a session using components of a content application 704 on the client device 702 and data stored locally on that client device. In at least one embodiment, a content application 724 executing on a computer or processor 720 (e.g., a cloud server or control system) may initiate a session associated with at least one client device 702 (e.g., a vehicle or robot), as may use a session manager and user data stored in a user database 736, and can cause content such as liquid coolant or server thermal data to be selected and/or retrieved from a repository 734 to be used by a testing module 732 to calculate one or more performance metrics for a monitoring module 728, which can provide flow data or thermal data to a control module 730 to control a flow or temperature, in an environment where the data is to be used to determine appropriate operation.

A content manager 726 may work with at these various modules to perform testing and analysis, and potentially instruct any actions to be taken in response to a performance metric failing to satisfy an operational requirements. At least a portion of this data or instructional content can be transmitted to the client device 702 and/or a physical device 770 using an appropriate transmission manager 722 to send by download, streaming, or another such transmission channel. An encoder may be used to encode and/or compress at least some of this data before transmitting to the client device 702. In at least one embodiment, the client device 702 receiving such content can provide this content to a corresponding content application 704, which may also or alternatively include a graphical user interface 710, a flow monitor module 712, and a control module 714 for use in providing, synthesizing, rendering, compositing, modifying, or using content for presentation, navigation, control, (or other purposes) on or by the client device 702, such as may be transmitted to the physical device 770.

In some embodiments, the computer/processor 720 and client device 702 may be able to communicate directly without needing to transmit data over a network 740, in order to avoid issues with latency and availability, etc.. A decoder may also be used to decode data received over the network 740 for presentation via client device 702, such as imaging content or performance metrics through a display device 706 and audio, such as corresponding sounds or synthesized speech, through at least one audio playback device 708, such as speakers or headphones. In at least one embodiment, at least some of this content may already be stored on, rendered on, or accessible to client device 702 such that transmission over a network 740 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 720, or user database 736, to the client device 702. In at least one embodiment, at least a portion of this content can be obtained, enhanced, and/or streamed from another source, such as a third party service 760 or other client device 750, that may also include a content application for generating, updating, enhancing, or providing map content. In at least one embodiment, portions of this functionality can be performed using multiple computing components, or multiple processors within one or more computing components, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates as liquid manifolds. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

In the following description, numerous specific details are set forth to provide a more thorough understanding of at least one embodiment. However, it will be apparent to one skilled in the art that the inventive concepts may be practiced without one or more of these specific details.

Other variations are within the spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of the term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause the computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of the instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operations such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment, combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to the practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, a ‘processor’ may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as the system may embody one or more methods and methods may be considered a system.

In present document, references may be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways, such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing an entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system of a flexible cold plate assembly, comprising:
a flexible cold plate comprising heat removal surface extensions and comprising a plurality of discontinuities within the heat removal surface extensions, the discontinuities to allow conformance or flexing in the flexible cold plate to support warping associated with an underlying computing component.

2. The system of claim 1, wherein the discontinuities are cross-cuts which are perpendicular to a direction of flow of a fluid through the heat removal surface extensions.

3. The system of claim 2, further comprising:
a distribution seal to provide a seal at a first top of the heat removal surface extensions and at a second top of the plurality of discontinuities, wherein the distribution seal is configured for further conforming or flexing, with respect to the flexible cold plate, upon the warping associated with the computing component.

4. The system of claim 3, wherein the distribution seal comprises one or more of:
a flat surface on a bottom side to provide the seal at the first top of the heat removal surface extensions and the second top of the plurality of discontinuities, or
a top distribution seal portion and a bottom distribution seal portion, the bottom distribution seal portion to provide the seal at the first top of the heat removal surface extensions and the second top of the plurality of discontinuities, and the top seal distribution portion to provide a further seal between a distribution manifold and the bottom distribution seal portion.

5. The system of claim 3, further comprising:
a distribution manifold over the distribution seal and comprising manifold distribution channels, the distribution manifold to distribute fluid through the distribution seal and into the heat removal surface extensions and to provide a further seal over the manifold distribution channels to prevent the fluid from crossing between inlet and outlet ports.

6. The system of claim 5, wherein the distribution seal comprises U-shaped features on a top side to provide the further seal over the manifold distribution channels.

7. The system of claim 5, further comprising:
a manifold lid fastened to the distribution manifold and over the distribution seal, the manifold lid to guide the fluid from a fluid inlet of the manifold lid to the manifold distribution channels of the distribution manifold, wherein the manifold distribution channels allow the fluid to reach the heat removal surface extensions of the flexible cold plate.

8. The system of claim 5, further comprising:
a top plate in the distribution seal to provide a channel seal between distribution channels of the distribution manifold;
a bottom plate in the distribution seal, the bottom plate to allow the seal at the first top of the heat removal surface extensions and at the second top of the plurality of discontinuities; and
a spring between the top plate and the bottom plate, the spring to allow one or more of the top plate and the bottom plate to further conform or flex in the distribution seal, with respect to the flexible cold plate, upon warping associated with the computing component.

9. The system of claim 8, wherein the bottom plate is configured to vertically move closer or farther with respect to the top plate, as part of the further conforming or flexing in the distribution seal.

10. The system of claim 3, wherein the distribution seal comprises flow restrictions to block or limit the fluid from reaching portions of the flexible cold plate associated with a passive or less active part of the underlying computing component, the passive or less active part associated with a lower activity measure relative to at least one active part of the computing component.

11. A flexible cold plate assembly comprising a flexible cold plate which allows for conformance or flexing to support warping associated with an underlying computing component, wherein the conformance or flexing is based, at least in part, on heat removal surface extensions comprising a plurality of discontinuities therein, and wherein the plurality of discontinuities is perpendicular to a direction of flow of a fluid through the heat removal surface extensions.

12. The flexible cold plate assembly of claim 11, further comprising:
a distribution seal to provide a seal at a first top of the heat removal surface extensions and at a second top of the plurality of discontinuities, wherein the distribution seal is configured for further conforming or flexing, with respect to the flexible cold plate, upon warping associated with the computing component.

13. The flexible cold plate assembly of claim 12, further comprising:
a manifold lid fastened to a distribution manifold and over the distribution seal, the manifold lid to guide the fluid from a fluid inlet of the manifold lid to manifold distribution channels of the distribution manifold, wherein the manifold distribution channels allow the fluid to reach the heat removal surface extensions of the flexible cold plate.

14. The flexible cold plate assembly of claim 12, further comprising:
a top plate of the distribution seal to provide a channel seal over the heat removal surface extensions and over the plurality of discontinuities;
a bottom plate in the distribution seal, the bottom plate to allow the seal at the first top of the heat removal surface extensions and at the second top of the plurality of discontinuities; and
a spring between the top plate and the bottom plate, the spring to allow one or more of the top plate and the bottom plate to perform a further conforming or flexing in the distribution seal, with respect to the flexible cold plate, upon warping associated with the computing component.

15. A method for cooling in a computing environment, the method comprising:
determining a flexible cold plate for association with an underlying computing component of the computing environment;
associating the flexible cold plate with the computing component, the flexible cold plate comprising heat removal surface extensions and comprising a plurality of discontinuities within the heat removal surface extensions and perpendicular to a direction of flow of fluid through the heat removal surface extensions, the discontinuities to allow conformance or flexing in the flexible cold plate to support warping associated with the computing component; and
using a distribution seal to provide a seal at a first top of the heat removal surface extensions, at a second top of the plurality of discontinuities, wherein the distribution seal is configured for further conforming or flexing, with respect to the flexible cold plate, upon warping associated with the computing component.

16. A silicon package comprising a component to perform a workload and associated with a cold plate assembly, the cold plate assembly comprising a flexible cold plate which allows for conformance or flexing to support warping associated with the silicon package, wherein the conformance or flexing is based, at least in part, on heat removal surface extensions comprising a plurality of discontinuities therein, and wherein the plurality of discontinuities are perpendicular to a direction of flow of fluid through the heat removal surface extensions.

17. A datacenter comprising:
one or more racks comprising one or more server trays;
one or more components in the one or more racks, the one or more components to perform at least part of a workload in the datacenter; and
a cold plate assembly associated with the one or more components, the cold plate assembly comprising a flexible cold plate which allows for conformance or flexing to support warping associated with the one or more components, wherein the conformance or flexing is based, at least in part, on heat removal surface extensions comprising a plurality of discontinuities therein, and wherein the plurality of discontinuities are perpendicular to a direction of flow of fluid through the heat removal surface extensions.

18. A flexible cold plate assembly comprising a flexible cold plate which allows for conformance or flexing to support warping associated with an underlying computing component, wherein the conformance or flexing is based, at least in part, on heat removal surface extensions provided over a base plate having a thickness that is in a range of one of: 100 microns to 200 microns, 200 microns to 300 microns, 300 microns to 400 microns, or 400 microns to 500 microns.

19. A flexible cold plate assembly comprising a flexible cold plate which allows for conformance or flexing to support warping associated with an underlying computing component, wherein the conformance or flexing is based, at least in part, on heat removal surface extensions provided over a base plate having a thickness of between 100 microns and 500 microns and is additionally based, at least in part, on the heat removal surface extensions comprising a plurality of discontinuities therein, wherein the plurality of discontinuities are perpendicular to a direction of flow of fluid through the heat removal surface extensions.

20. A flexible cold plate comprising heat removal surface extensions and comprising a plurality of discontinuities within the heat removal surface extensions, the discontinuities to allow conformance or flexing in the flexible cold plate to support warping associated with an underlying computing component.
